(19) United States
(12) Patent Application Publication
(10) Pub. No.: US 2025/0357137 A1
(43) Pub. Date: Nov. 20, 2025

(54) DEPOSITION FILM TUNING AND TEMPERATURE TUNING FOR ETCH UNIFORMITY

(71) Applicant: Applied Materials, Inc., Santa Clara, CA (US)

(72) Inventors: Sarah Michelle BOBEK, Sunnyvale, CA (US); Rana HOWLADER, San Jose, CA (US); Abdul Aziz KHAJA, San Jose, CA (US); Bo QI, San Jose, CA (US); Deenesh PADHI, Sunnyvale, CA (US); Karthik JANAKIRAMAN, San Jose, CA (US)

(21) Appl. No.: 19/208,727

(22) Filed: May 15, 2025

Related U.S. Application Data
(60) Provisional application No. 63/648,435, filed on May 16, 2024.

(51) Int. Cl. H01L 21/311

(52) U.S. Cl. CPC H01L 21/31144

(57) ABSTRACT

Aspects generally relate to methods and systems for optimizing a critical dimension (CD) etch profile of a hardmask (HM) to create etch uniformity for underlying material layers. The method includes forming an initiation layer on a dielectric film in a first pass, forming a carbon layer on the initiation layer in a second pass, the initiation layer and the carbon layer collectively defining a hardmask (HM), and the initiation layer configured to adjust a critical dimension (CD) etch profile of the HM, etching the HM to a top surface of the dielectric film, and etching the dielectric film to create a plurality of pillars with straight sidewalls. Adjusting the CD etch profile of the HM results in substantially straight HM sidewall openings. Further, formation of the substantially straight HM sidewall openings cause the plurality of pillars to have straight sidewalls.

### CROSS-REFERENCE TO RELATED APPLICATIONS

This application claims benefit of U.S. provisional patent application Ser. No. 63/648,435, filed May 16, 2024, which is herein incorporated by reference in its entirety.

### BACKGROUND

### Field

Aspects generally relate to methods and systems for optimizing a critical dimension (CD) etch profile of a hardmask (HM) to create etch uniformity for underlying material layers.

### Description of the Related Art

The etching process in semiconductor manufacturing involves several parameters that influence the rate and uniformity of material removal from the substrate. A hardmask acts as a protective layer during an etching process, thus allowing precise control over the dimensions and depths of the etched features. The hardmask ensures accurate pattern transfer onto the underlying layers. The hardmask is resistant to the etchant used in the process, thereby shielding the areas where the hardmask is present. This protection ensures that only the exposed areas of the underlying material are etched away, while the regions covered by the hardmask remain intact. If the etching of the hardmask is not precise, this may lead to several undesirable outcomes in the semiconductor fabrication process, including pattern distortion, dimension inaccuracy, under-etching, over-etching, poor selectivity, process integration issues, variability and yield loss, and mask damage.

Therefore, there is a need for improved methods and systems that facilitate etch geometry uniformity in semiconductor fabrication processes.

### SUMMARY

Aspects generally relate to methods and systems for optimizing a critical dimension (CD) etch profile of a hardmask (HM) to create etch uniformity for underlying material layers.

In one implementation, a method of includes forming an initiation layer on a dielectric film in a first pass, forming a carbon layer on the initiation layer in a second pass, the initiation layer and the carbon layer collectively defining a hardmask (HM), and the initiation layer configured to adjust a critical dimension (CD) etch profile of the HM, etching the HM to a top surface of the dielectric film, and etching the dielectric film to create a plurality of pillars with straight sidewalls.

In one implementation, a method includes forming a hardmask (HM) on a dielectric film, adjusting a temperature during deposition of the HM to adjust a critical dimension (CD) etch profile of the HM, etching the HM to a top surface of the dielectric film, and etching the dielectric film to create a plurality of pillars with straight sidewalls.

In one implementation, a method includes forming an initiation layer on a dielectric film in a first pass, forming a carbon layer on the initiation layer in a second pass, the initiation layer and the carbon layer collectively defining a hardmask (HM), adjusting a temperature during deposition of the HM, where forming the initiation layer and adjusting a temperature during deposition of the HM collectively adjust a critical dimension (CD) etch profile of the HM, etching the HM to a top surface of the dielectric film, and etching the dielectric film to create a plurality of pillars with straight sidewalls.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, as the disclosure may admit to other equally effective embodiments.

FIG. 1 is a cross-sectional view of a process chamber, according to one implementation.

FIGS. 2A-2C illustrate a process flow for creating pillars within an oxide nitride (ON) film, according to one implementation.

FIG. 3 is a cross-sectional view of the hardmask (HM) formed over the ON film and a critical dimensions (CD) etch profile adjacent the HM, according to one implementation.

FIG. 4 illustrates bow adjustment to the CD etch profile of the HM, according to one implementation.

FIG. 5 is a flowchart of a method for adjusting the CD etch profile of the HM using an initiation layer approach, according to one implementation.

FIG. 6 is a flowchart of a method for adjusting the CD etch profile of the HM using a temperature adjusting approach, according to one implementation.

FIG. 7 is a flowchart of a method for adjusting the CD etch profile of the HM using a combination of the initiation layer approach and the temperature adjustment approach, according to one implementation.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Aspects generally relate to methods and systems for optimizing a critical dimension (CD) etch profile of a hardmask (HM) to create etch uniformity for underlying material layers.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor substrates. Substrates may be exposed to a pretreatment process to polish, etch, reduce, oxidize, hydroxylate, anneal and/or bake the substrate surface. In addition to film processing directly on the surface of the substrate, any of the film processing steps disclosed may also be performed on an under-layer formed on the substrate as disclosed in more detail below, and the term “substrate surface” is intended to include such under-layer as the context indicates. Thus for example, where a film/layer or partial film/layer has been deposited onto a substrate surface, the exposed surface of the newly deposited film/layer becomes the substrate surface.

Offset etch geometry uniformity in semiconductors refers to the consistency of the etching process across a substrate, particularly in relation to the desired pattern or structure being etched. In semiconductor manufacturing, etching is a step used to selectively remove material from the surface of a substrate to create patterns or features such as transistors, interconnects, or other circuit elements. Offset etch geometry uniformity ensures that the etching process produces consistent dimensions and shapes across the substrate, without significant deviations or variations.

When referring to offset etch geometry uniformity, “offset” typically refers to any deviation from the intended dimensions or shapes due to factors such as variations in etch rates, chemical concentrations, temperature, or other process parameters. “Geometry uniformity” indicates that these deviations should be minimized or controlled to ensure that the resulting semiconductor devices meet design specifications and perform reliably.

Offset etch geometry uniformity is achieved by precise control of the etching process parameters, as well as thorough monitoring and adjustment to compensate for any variations that may occur during manufacturing. This ensures that semiconductor devices have consistent performance characteristics and meet quality standards.

Offset etch geometry uniformity can be achieved by critical dimension (CD) control. Critical dimension refers to the key geometric parameters of features or patterns on a substrate, such as the width, height, or spacing of lines, trenches, or other structures. CD control is the process of precisely managing and maintaining these critical dimensions within specified tolerances throughout the semiconductor fabrication process. Achieving tight CD control is beneficial for ensuring the performance, functionality, and reliability of semiconductor devices. Variations in critical dimensions can affect device characteristics, electrical properties, and yield. CD control is particularly useful in advanced semiconductor technologies with shrinking feature sizes, where even small deviations can have significant impacts on device performance.

CD control involves at least process optimization, metrology and measurement, feedback and correlation, and advance process control.

Semiconductor manufacturers optimize various fabrication processes, such as photolithography, etching, deposition, and ion implantation, to achieve precise control over critical dimensions. This may involve fine-tuning process parameters, materials, and equipment to minimize variability and achieve the desired feature sizes.

Accurate metrology techniques and tools are used to measure critical dimensions on substrates with high precision. Advanced metrology tools, such as scanning electron microscopes (SEM) or atomic force microscopes (AFM), are employed to characterize feature sizes and ensure compliance with design specifications.

Real-time monitoring and feedback mechanisms are implemented to detect deviations from target critical dimensions during the fabrication process. If variations are detected, corrective actions may be taken, such as adjusting process parameters or calibrating equipment, to bring the critical dimensions back within acceptable tolerances.

Advanced process control (APC) methodologies and software algorithms are utilized to continuously optimize semiconductor manufacturing processes and maintain CD control. APC systems use statistical analysis, machine learning, and predictive modeling to predict and prevent deviations in critical dimensions.

CD control is beneficial for achieving high yields, ensuring device performance, and meeting the stringent quality requirements of semiconductor devices. Semiconductor manufacturers employ a combination of process optimization, metrology, feedback mechanisms, and advanced process control techniques to achieve tight CD control throughout the fabrication process.

The example embodiments optimize the CD etch profile of a hardmask (HM) to create etch uniformity for underlying material layers. The CD etch profile of the HM is adjusted by employing either an initiation layer approach, a temperature tuning or adjustment approach, or a combination of the initiation layer approach and the temperature tuning approach. Such approaches open the bottom portion of the CD etch profile of the HM to create straight or linear surface openings within the HM that result in the creation of straight pillars in underlying material layers. Thus, the shape of the openings of the HM affect the shape of the pillars formed in the underlying material layers. The shape of the pillars formed in the underlying material layers may affect the semiconductor device operation.

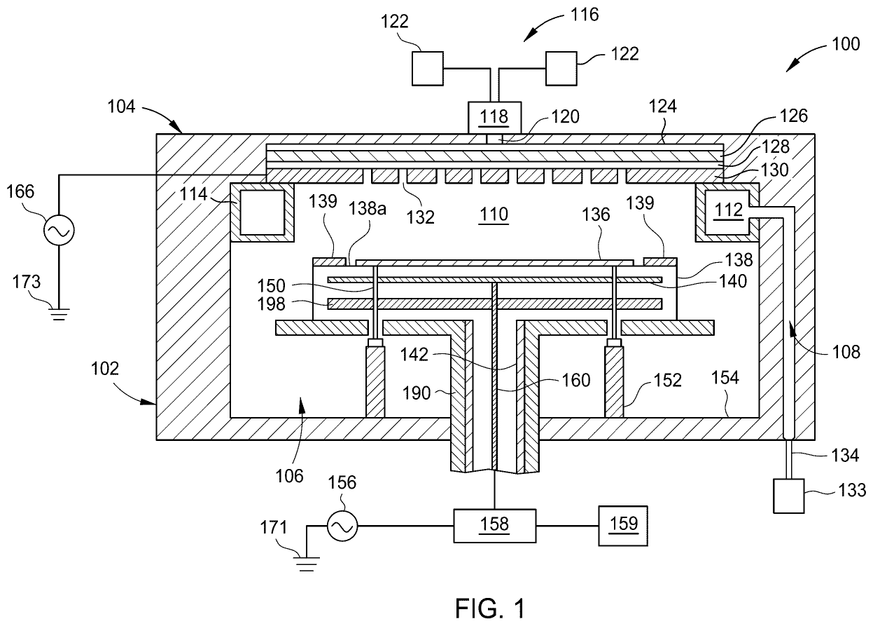

FIG. 1 is a schematic cross-sectional view of a chamber 100 with a pedestal 138 disposed therein, according to one implementation. The chamber 100 is for example a substrate processing chamber for fabricating semiconductors. The chamber 100 may be a deposition chamber such as a vapor deposition chamber, for example a chemical vapor deposition (CVD) chamber or a plasma enhanced CVD (PECVD) chamber. The chamber 100 has a chamber body 102 and a chamber lid 104. The chamber body 102 includes an internal volume 106 therein and a pumping path 108. The internal volume 106 is the space defined at least partially by the chamber body 102 and the chamber lid 104. The pumping path 108 is a path formed in the chamber body 102 coupled to a pumping volume 112 formed in a pumping plate 114. The pumping path 108 facilitates removal of gases from the internal volume 106.

The chamber 100 includes a gas distribution assembly 116 coupled to or disposed in the chamber lid 104 to deliver a flow of one or more gases into a processing region 110. The gas distribution assembly 116 includes a gas manifold 118 coupled to a gas inlet passage 120 formed in the chamber lid 104. The gas manifold 118 receives a flow of gases from one or more gas sources 122 (two are shown). The flow of gases received from the one or more gas sources 122 distributes across a gas box 124, flows through a plurality of openings of a backing plate 126, and further distributes across a plenum 128 defined by the backing plate 126 and a faceplate 130. The flow of gases then flows into a processing region 110 of the internal volume 106 through a plurality of openings 132 of the faceplate 130. A pump 133 is connected to the pumping path 108 by a conduit 134 to control the pressure within a processing region 110 and to the exhaust gases and byproducts from the processing region 110 through the pumping volume 112 and pumping path 108.

The internal volume 106 includes a pedestal 138 that supports a substrate 136 within the chamber 100. The pedestal 138 includes a heater 198 and an electrode 140 disposed within the pedestal 138. The electrode 140 may include a conductive mesh, such as a tungsten-containing, copper-containing, or molybdenum-containing conductive radio frequency (RF) mesh. The heater 198 may include any material used for heating, including an alternating current (AC) coil. FIG. 1 illustrates the heater 198 as disposed below the electrode 140. However, it is contemplated that the heater 198 may alternatively be disposed above the electrode 140.

The pedestal 138 is movably disposed in the internal volume 106 by a stem 142 coupled to a lift system. Movement of the pedestal 138 facilitates transfer of the substrate 136 to and from the internal volume 106 through a slit valve formed through the chamber body 102. The pedestal 138 may also be moved to different positions for processing, insertion, and/or removal of the substrate 136. The pedestal 138 may also have openings disposed therethrough, through which a plurality of lift pins 150 may be movably disposed. In the lowered position, the plurality of lift pins 150 are projected from the pedestal 138 by contacting a lift plate 152 coupled to a bottom 154 of the chamber body. Projection of the lift pins 150 places the substrate 136 in a spaced-apart relation from the pedestal 138 to facilitate the transfer of the substrate 136.

The pedestal 138 in the implementation shown in FIG. 1 includes a support surface 138a that is configured to support a substrate 136 thereon. The support surface 138a and/or the pedestal 138 may be heated. During processing the substrate 136 is disposed on the support surface 138a. The pedestal 138 also includes an edge ring 139 disposed on the support surface 138a around the substrate 136. During substrate processing, as gases flow into the processing region 110, the heater 198 heats the pedestal 138 and the support surface 138a. Also during substrate processing, the electrode 140 propagates radio frequency (RF) energy, alternating current (AC), or direct current (DC) to facilitate plasma processing in the processing region 110 and/or to facilitate chucking of the substrate 136 to the pedestal 138. The heat, gases, and energy from the electrode 140 facilitate deposition of a film onto the substrate 136 during substrate processing.

In the implementation shown, a radio frequency (RF) source 156 is coupled to the electrode 140 disposed within the pedestal 138 through a matching circuit 158. Although an RF source 156 is illustrated, the present disclosure contemplates that other power sources may be used, such as an alternating current (AC) power source or direct current (DC) power source. The matching circuit 158 is electrically coupled to the electrode 140 by a conductive rod 160. The matching circuit 158 is also electrically coupled to the heater 198. A power source 159 is configured to provide power to the heater 198. The power source 159 may provide AC power or DC power to the heater 198 to generate heat. The faceplate 130, which is grounded via coupling to the chamber body 102 and the electrode 140 facilitate formation of a capacitive plasma coupling. The RF source 156 connects to ground 171. A second RF source 166 also is configured to provide RF energy to the chamber 100. The second RF source 166 is connected to ground 173. Although a second RF source 166 is illustrated, the present disclosure contemplates that other power sources may be used, such as an alternating current (AC) power source or direct current (DC) power source.

When RF power is supplied to the electrode 140, an electric field is generated between the faceplate 130 and the pedestal 138 such that atoms of gases present in the processing region 110 between the pedestal 138 and the faceplate 130 are ionized and release electrons. The ionized atoms accelerate to the pedestal 138 to facilitate film formation on the substrate 136. In one example, the processing region 110 is between the faceplate 130 on a first side of the processing region 110, and the support surface 138a and the edge ring 139 on a second side of the processing region 110. It is contemplated that the chamber 100 may be configured as top-bias or bottom-bias for plasma generation.

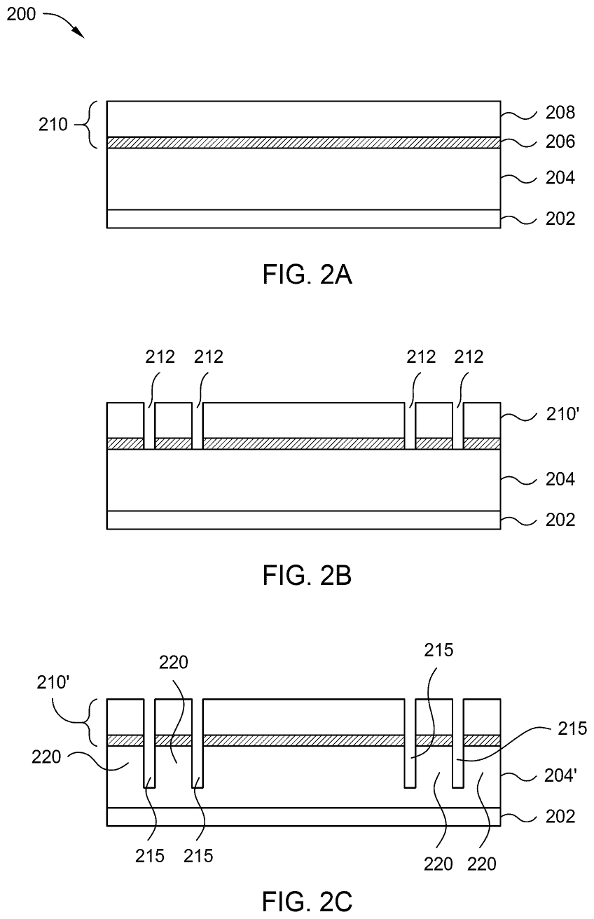

FIGS. 2A-2C illustrate a process flow 200 for creating pillars within an oxide nitride (ON) film, according to one implementation.

In FIG. 2A, an oxide nitride (ON) film 204 is formed over a substrate 202. The ON film 204 can be referred to as a dielectric layer or insulating layer. In one example, the ON film 204 can be alternating layers of silicon oxide and silicon nitride layers. In another example, the ON film can be an oxynitride film. A hardmask (HM) 210 is then formed over the ON film 204. The HM 210 can include two layers. The first layer may be an initiation layer 206 and the second layer may be a carbon layer. The initiation layer 206 can also be referred to as a base layer. The initiation layer 206 is formed at the base of the HM 210. The initiation layer 206 can also be a carbon-based layer. The initiation layer 206 is formed in a first pass and the carbon layer 208 is formed in a second pass. The initiation layer 206 and the carbon layer 208 collectively form the HM 210. The multi-pass formation refers to the HM 210 formed through multiple operations or passes. The multi-pass formation is beneficial in achieving the optimized CD etch profile of the HM 210.

The initiation layer 206 is thinner than the carbon layer 208. The initiation layer 206 can have a thickness of about 11-11.5 kÅ. The carbon layer 208 can have a thickness of about 22-23.5 kÅ. Therefore, in one example, the carbon layer 208 can be twice as thick as the initiation layer 206.

The present disclosure contemplates that other hardmask thickness values may be used. The present disclosure contemplates that the one or more carbon hardmask layers of the substrate may be used to form a memory device or a logic device. The hardmask composition includes carbon and can include one or more dopants such as boron, tungsten, and/or nitrogen.

The depositing of the one or more carbon hardmask layers occurs in the chamber 100 after transferring the substrate into the chamber 100. Depositing the one or more carbon hardmask layers includes flowing one or more reactive precursor gases into the deposition chamber and generating a plasma in the deposition chamber to deposit reactants on the plurality of base films to form the one or more carbon hardmask layers. The one or more reactive precursor gases include one or more of carbon, hydrogen, and/or nitrogen, such as nitrogen (N₂), hydrogen (H₂), acetylene (C₂H₂) and/or propene (C₃H₆). The generating of the plasma includes flowing one or more gases, such as inert gases into the chamber 100 while applying electrical power (such as radiofrequency power) to generate the plasma. The one or more inert gases include one or more of helium and/or argon. The plasma is an inert stabilizing plasma. The one or more reactive precursor gases flow at a first flow rate that is within a range of 100 standard cubic centimeters per minute (SCCM) to 2,000 SCCM. The one or more inert gases flow at a second flow rate that is within a range of 0 SCCM to 11,900 SCCM. A total flow rate adds together the first flow rate and the second flow rate. The total flow rate is within a range of 1,000 SCCM to 12,000 SCCM.

In particular, depositing the one or more carbon hardmask layers includes flowing one or more reactive precursor gases (e.g., a second gas mixture) into the chamber 100 through the gas distribution assembly 116 as a first gas mixture is removed from the chamber 100. Thus, the second gas mixture is flowed into the chamber 100 through the gas distribution assembly 116 while the first gas mixture is removed from the chamber 100. The second gas mixture may include mixtures of precursor gases such as argon and propene, however, other similar gases may be used such as nitrogen, ethylene, oxygen, tungsten hexafluoride, diborane, tungsten, pentacarbonyl 1-methylbutylisonitrile, silane, or nitrous oxide. The second gas mixture may be flowed into the chamber 100 at a rate of between about 1000 sccm and 4000 sccm, such as about 2500 sccm, for example.

As noted above, the initiation layer 206 can also be a carbon-based layer. The composition of the initiation layer 206 may be 5-40% atomic percent hydrogen using the chemistries indicted above.

In FIG. 2B, an etch takes place to create trenches or openings 212 in the HM 210. The remaining HM can be designated as 210′. The etch stops at a top surface of the ON film 204. The etching can be e.g., wet etching or dry etching. The dry etching can be e.g., a reactive ion etch (RIE) or a plasma etch. In the instant case, a plasma etch may be performed in the chamber 100 of FIG. 1 to etch the HM 210.

In FIG. 2C, a second etch is performed to create openings 215 in the ON film 204. The openings 215 result in pillars 220 formed within the remaining ON film 204′. A plurality of pillars may be formed in the remaining ON film 204′. The second etch may also be a plasma etch performed in the chamber 100 of FIG. 1.

Etching is an operation used to selectively remove material from the surface of a substrate to create patterns or features such as transistors, interconnects, or other circuit elements. Offset etch geometry uniformity ensures that the etching process produces consistent dimensions and shapes across the substrate, without significant deviations or variations. “Geometry uniformity” indicates that these deviations should be minimized or controlled to ensure that the resulting semiconductor devices meet design specifications and perform reliably. Offset etch geometry uniformity is achieved by precise control of the etching process parameters, as well as thorough monitoring and adjustment to compensate for any variations that may occur during manufacturing.

In the example embodiments, to maintain geometry uniformity, the process of forming the HM 210 is changed to modify the etch profile of the HM 210. Stated differently, a change to the process of depositing a patterning film, such as the HM 210, results in a change to the etch profile of the HM. The shape of the openings of the HM 210 affect the shape of the pillars 220 formed in the ON film 204. The shape of the pillars 220 formed in the ON film 204 may affect the semiconductor device operation.

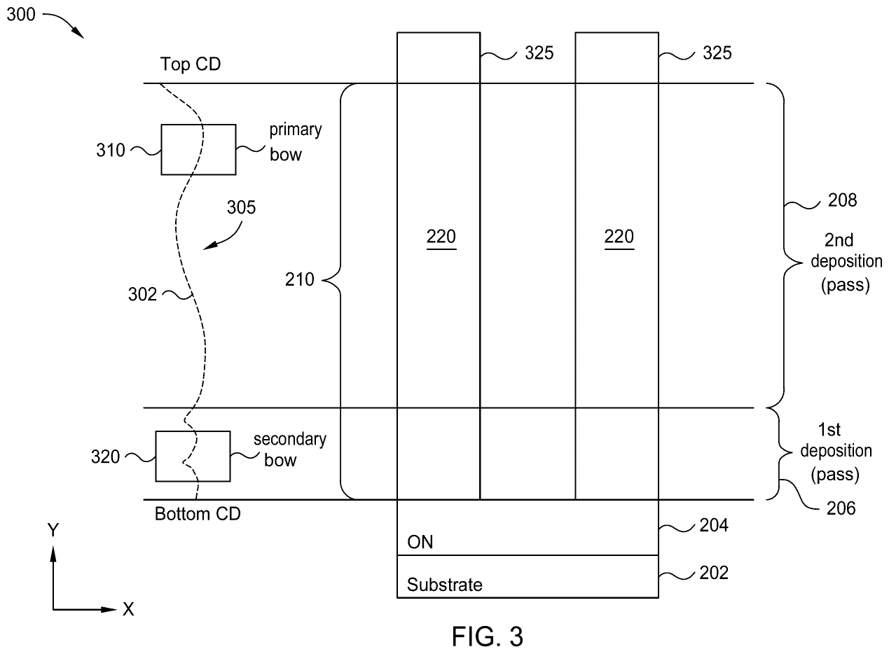

Customers may use various metrics to assess the quality of the etch to the HM 210, which in turn is an assessment or evaluation of the fidelity of the customers' patterns. One such metric is the critical dimension (CD). In the example embodiments, the CD profile can be optimized to create a more uniform CD etch. The etching of the HM 210 creates patterns or features such as openings 212 or trenches therein. The CD of the HM etch determines the smallest width or depth that can be achieved during the etching process. The CD of the HM etch directly impacts the performance and yield of semiconductor devices, and should be controlled precisely. The CD of the HM 210 or CD etch profile can be visualized as a line or trace with a number of bows or curves or curvatures or bends or arcs, as described below with reference to FIG. 3.

FIG. 3 is a schematic 300 of a cross-sectional view of the hardmask (HM) formed over the ON film and a critical dimensions (CD) etch profile adjacent the HM, according to one implementation.

The CD of the HM 210 or CD etch profile 305 can be visualized as a line or trace 302 with a number of bows or curves or curvatures or bends or arcs. The trace 302 with the bows can be positioned adjacent the sidewalls of the pillars 220 to indicate where along the surface of the pillars 220 such bows are present. The CD etch profile 305 includes a depth and a width. The depth can be represented on a Y-axis and the width can be represented on an X-axis. The CD etch profile 305 of the HM can be in the order of 30-70 nm.

In one example, the trace 302 depicts attributes of the pillars 220, such as a first bow or primary bow 310 and a second bow or secondary bow 320. The primary bow 310 may be formed at the upper portion of the CD etch profile 305 and the secondary bow 320 may be formed at the lower portion of the CD etch profile 305. The pillars may include a photomask 325. The photomask 325 may be a dark field advanced resolution contrast (DARC) material.

When a change is introduced to the HM formation process, the CD etch profile 305 of the HM also changes. Even a small change to the HM open profile may cause enough of a difference in pattern geometry to the underling ON film 204. In one example, the CD etch profile 305 changed at the top portion of the oxide nitride (ON) film 204, where a bridging effect was created. In other words, the CD at such portions of the ON film 204 exceeded acceptable CD ranges. The bridging effect at the top portions of the ON film 204 can cause a yield issue as certain customers perform a high aspect ratio etch. A high aspect ratio etch is where the depth of the etched feature is greater than their lateral dimensions, resulting in a significant difference between the height and width of the features.

In general, more non-uniformities are found at the edges of the substrate. In one example, the substrate can have a diameter of 300 mm with a radius of 150 mm. Thus, more non-uniformities may be present in a radial region ranging from 135 mm to 150 mm on the substrate. The radial region may be referred to as an edge region (e.g., the outermost 15 mm of the substrate).

Improvement of the CD etch profile 305 can be accomplished by adjusting the HM 210 itself. Adjusting the HM pertains to making the HM open profile (i.e., openings or trenches in the HM) straighter or substantially straight or linear. By making the HM open profile straighter, the ion deflection within the openings 212 or trenches of the HM 210 will be significantly reduced, thus resulting in straighter pillars (in the underlying layer), that is, the sidewalls of the pillars 220 will be substantially more straight or linear or perpendicular to the top surface of the substrate. Ideally, the sidewalls of the pillars 220 are completely straight or linear along their entire length.

Three approaches are presented for adjusting the CD etch profile 305 of the HM 210. The first approach is referred to as the initiation layer approach. The second approach is referred to as the temperature tuning or adjustment approach. The third approach is a combination of the first and second approaches.

The initiation layer approach and the temperature tuning approach change the HM open profile by changing the modulus of the HM 210. The modulus refers to an elastic modulus or Young's modulus. Young's modulus is the modulus of elasticity for tension or axial compression. The higher the modulus of the HM 210, the more difficult it is to etch the HM 210, which results in a smaller CD. The lower the modulus of the HM 210, the easier it is to etch the HM 210, which results in a larger CD. In the initiation layer approach, the modulus is changed by forming an initiation layer 206 at the base of the HM 210. In the temperature tuning approach, the modulus is changed by changing or tuning or adjusting the temperature during deposition of the HM 210 in the chamber 100.

In semiconductor manufacturing, a material with a higher modulus is stiffer and more resistant to deformation. A greater force is used to produce a given amount of deformation compared to a material with a lower modulus. In semiconductor manufacturing, materials with higher modulus may be used for structural elements or support structures where rigidity and dimensional stability are beneficial, such as in certain packaging or substrate materials. Conversely, a material with a lower modulus is less stiff and more compliant. It deforms more easily under applied force compared to a material with a higher modulus. In semiconductor applications, materials with lower modulus may be desirable for certain components where flexibility or cushioning properties are needed, such as in some types of encapsulants or adhesives used for bonding semiconductor devices. As noted above, the modulus refers to elastic modulus or Young's modulus.

In the initiation layer approach, the HM open profile is changed or altered by depositing a base layer or initiation layer. The base layer can be referred to as the initiation layer 206. In one example, the initiation layer 206 can have a thickness of about 1500 Å. In another example, the initiation layer 206 can have a thickness of less than 1500 Å. The initiation layer 206 provides for a softer film at the base of the HM 210 to open the bottom CD more. In one example, the Mohs hardness of the initialization layer 206 may be approximately 3 or less. The initiation layer 206 can thus provide for the formation of pillars 220 in the ON film 204 that are straight or linear or perpendicular with respect to the substrate.

Thus, the initiation layer approach can be referred to as a two-operation deposition or two-operation pass approach because the HM 210 includes two layers, that is, a carbon layer 208 layer and the initiation layer 206. The initiation layer 206 is deposited in a first pass and the carbon layer 208 is deposited in a second pass. The initiation layer 206 has a hydrogen content between 5-40% atomic percent hydrogen, which makes the initial layer 206 different than the carbon layer 208. The carbon layer 208 has a hydrogen content between 10-30% atomic percent hydrogen.

In summary, the multi-pass approach includes first depositing a base layer or the initiation layer 206 and then depositing the carbon layer 208 over the initiation layer 206 to form the HM 210. The initiation layer 206 is much thinner than the carbon layer 208. The initiation layer 206 is deposited during the first pass and the carbon layer 208 is deposited in the second pass. During the first pass, the film thickness is about 11-11.5 kÅ and during the second pass, the film thickness is about 22-23.5 kÅ. Thus, the thickness of the carbon layer 208 is different than the thickness of the initiation layer 206. In one example, the thickness of the carbon layer 208 is twice the thickness of the initiation layer 206.

During the first pass, the focus is on ensuring proper adhesion between the HM 210 and the substrate. The first pass may use a precursor that creates an initial thin, uniform, and adhesive layer that facilitates the subsequent deposition of the carbon layer. The temperature may be lower is the first pass to prevent excessive heating. Gas flows are controlled to create the desired surface chemistry for bonding and pressure may be set to maintain a stable deposition environment. During the second pass, the focus is to create a dense carbon layer. This will involve a different set of precursors used for carbon deposition, such as hydrocarbon-based gases. The temperature in the second pass may be higher to enhance the formation of the carbon film. Gas flows can be adjusted to provide for a consistent carbon film growth rate and the pressure may be higher than the first pass to ensure proper film density and uniformity. Plasma setting in the second pass may be more aggressive than the first pass to facilitate decomposition of the carbon precursors.

In the first pass, the precursors may include at least one of methane, acetylene, ethylene, propylene, and spin-on-carbon (SOC). Other carbon precursors may also be used based on the application. The temperature may be about 150 degrees Celsius (° C.) to 300° C. This temperature may ensure adequate adhesion without excessive heating. The gas flow rates may be kept low, e.g., 10-50 sccm for SiH₄. The pressure may be kept low in the range of, e.g., 50-200 mTorr and the plasma settings may include low plasma power set at about 50-200 W.

In the second pass, the precursors may include methane (CH₄) or acetylene (C₂H₂) or other carbon precursors based on the application. The temperature may be about 250° C. to 450° C. Higher temperatures improve the rate of carbon film growth. The gas flow rates may be in the range of about 20-100 sccm for methane. The pressure may be kept higher in the second pass in the range of about 200-500 mTorr to promote better film density and ensure uniformity in the carbon film growth across the substrate. The plasma settings can range from about 200 W to 1000 W depending on the desired film properties.

Adjusting the temperature can improve critical dimension (CD) performance. CD performance refers to the accuracy and precision with which the critical features on a semiconductor substrate are defined and maintained during the fabrication process. In the temperature adjustment approach, the temperature adjustment is achieved by adjusting a temperature setting of a temperature controller. The tunable setting is used to adjust or tune an inner zone temperature and an outer zone temperature of a substrate support, and thus, of the substrate disposed thereon. The temperature can be controlled by the pedestal 138 in the chamber 100. The pedestal 138 is a platform or stage upon which the substrate is placed during various processing operations. The pedestal 138 serves as a support structure for the substrate and secures the substrate in place during processing. The temperature of the pedestal 138 can affect the chemical stability of the carbon-based materials, that is, that the stability of carbon molecules control or influence chemical reactions. The temperature can also be adjusted to improve adhesion of the carbon-based layers to the substrate and to achieve desired film quality. By adjusting the temperature, the carbon atoms can more effectively interact with the substrate, reducing the likelihood of poor adhesion, which can affect the integrity of the film. Ensuring uniform deposition and reducing stress-induced distortions can lead to more stable and precise CD control. The temperature can further be adjusted to prevent substrate degradation, warping, or other undesirable effects during the deposition process. By adjusting the temperature during deposition, the substrate maintains structural integrity, preventing deformation. A stable, non-degraded substrate allows for more uniform and precise film deposition, which translates to more defined features and better CD control.

During film deposition, temperature influences the film's uniformity. At higher temperatures, films may be smoother, which can help maintain a more uniform CD across the substrate. At lower temperatures, films may have a rougher surface causing patterning inconsistencies. By adjusting the temperature, the film thickness and uniformity can be improved, leading to more consistent CD features. Also, films like hardmasks may experience mechanical stress during processing. Stress can distort the film and cause warping, which can result in undesired changes to the CD. Temperature adjustments can reduce the mechanical stress by ensuring that thermal expansion coefficients of layers match to prevent deformation during cooling or heating. The alignment of stress between layers ensure that features retain their intended dimensions after thermal processing, thus improving CD.

The HM 210 is thus deposited with a tunable etch profile using adjustable settings of the chamber 100. In one example, this is accomplished through hardware controls. Hardware controls can include a PID temperature tuning of the heater 198 of the pedestal 138 by creating a gradient in the film based on the time or the depth of the HM 210. In another example, this is accomplished through process controls. Process controls can include gas ratio for film property targeting of the initiation layer, thus creating low stress and a low modulus base layer film.

Therefore, fine-tuning the HM 210 involves implementing a gas flow change at the bottom CD to open the HM profile at the bottom portion of the HM, which is adjacent the top portion of the ON film 204. The HM 210 is adjusted to make the hardmask open profile straighter. Making the HM open profile straighter refers to modifying the shape of openings or trenches in the HM 210 so that the openings are more uniform and linear. This reduces ion deflections during processes like ion etching or ion implantation. If the openings or trenches are irregular or misaligned, ions may deviate from their intended path, leading to sidewalls that are irregular (i.e., not straight). As such, by straightening the HM profile, ion deflections are reduced, leading to more uniform, straight sidewalls in the underlying pillars.

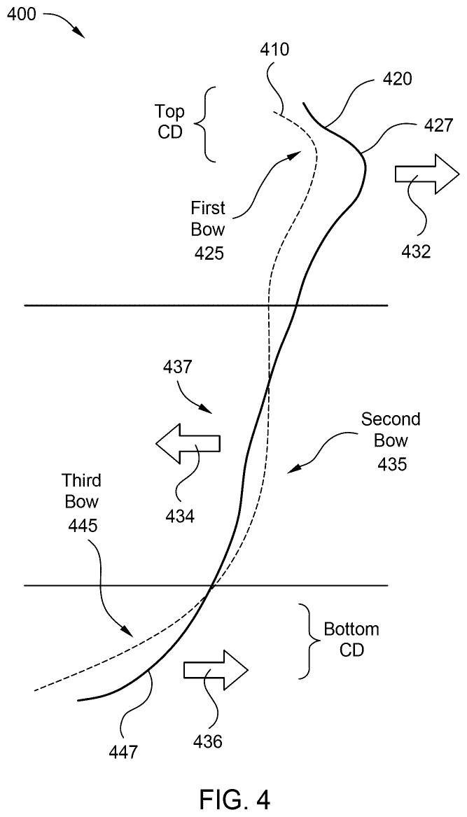

In the typical case, the temperature is adjusted so that the extinction coefficient (k) and the stress of the HM 210 matches the k and stress of the ON film 204. In the example embodiments, etch profile adjustability is accomplished through temperature targeting. Temperature targeting is employed across the surface of the HM 210. As noted above, more non-uniformities are present at the edge of the substrate. This outer circumferential area of the substrate may be more challenging to accurately process. The temperature adjustment provides for more accurate adjustment of this outer circumferential region of the substrate. Adjusting the temperature involves dynamically changing the temperature to obtain the desired CD etch profile of the HM 210 as described below with reference to FIG. 4.

FIG. 4 illustrates bow adjustment to the CD etch profile of the HM, according to one implementation.

The schematic 400 depicts the actual CD etch profile 410 (during deposition or fabrication) and the customer desired CD etch profile 420. By implementing the initiation layer approach or the temperature tuning approach or a combination thereof, the CD etch profile of the HM 210 can be fine-tuned to match the customer desired CD etch profile 420. The actual CD etch profile 410 includes a plurality of bows or curves or arcs. The upper portion of the actual CD etch profile 410 may include a first bow 425. The middle portion of the actual CD etch profile 410 may include a second bow 435. The lower portion of the actual CD etch profile 410 may include a third bow 445.

The first bow 425 can be shifted to the right (arrow 432) to match the bow 427 of the customer desired CD etch profile 420. The second bow 435 can be shifted to the left (arrow 434) to match the bow 437 of the customer desired CD etch profile 420. The third bow 445 can be shifted to the right (arrow 436) to match the bow 447 of the customer desired CD etch profile 420. Thus, the CD etch profile of the HM can be shifted as various points along the trace or line (represented by the actual CD etch profile 410) to match the desired trace or line (represented by the customer desired CD etch profile 420).

Therefore, the CD etch profile of the HM can be adjusted or modified or fine-tuned by selectively shifting the actual CD etch profile 410 at one or more targeted locations to create a match with the customer desired CD etch profile 420.

The improvement of the shift from the actual CD etch profile of the HM to the desired CD etch profile of the HM can be in the range of, e.g., about 100 nm. The improvement of the CD etch profile of the HM can be achieved initiation layer approach or the temperature tuning approach or a combination thereof. The improvement can result in creating a CD etch profile for the HM where the surface of the openings in the HM are substantially straight or linear or perpendicular to the substrate, which in turn cause the pillars formed in underlying layers to also exhibit straight or linear sidewalls.

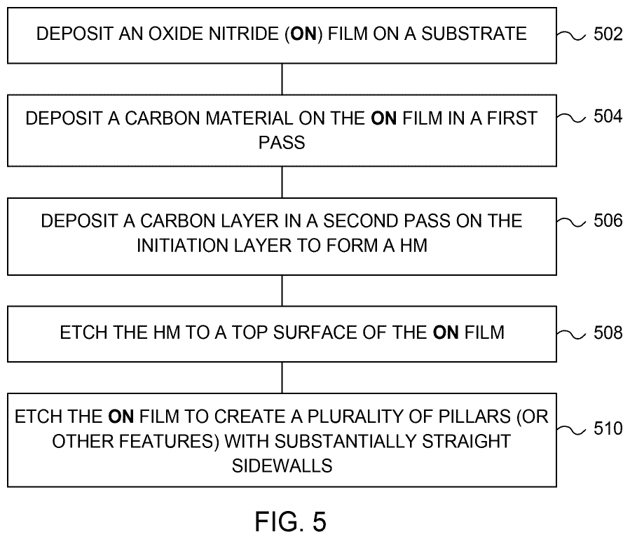

FIG. 5 is a flowchart of a method for adjusting the CD etch profile of the HM using an initiation layer approach, according to one implementation.

At block 502, an oxide nitride (ON) film is deposited on a substrate.

At block 504, a carbon material is deposited on the ON film in a first pass, the carbon material being an initiation layer configured to further open a bottom CD of the HM.

At block 506, a carbon layer is deposited in a second pass on the initiation layer to form a HM. The HM includes both the carbon layer and the initiation layer as its base layer.

At block 508, the HM is etched to a top surface of the ON film.

At block 510, the ON film is etched to create a plurality of pillars (or other features) with substantially straight sidewalls.

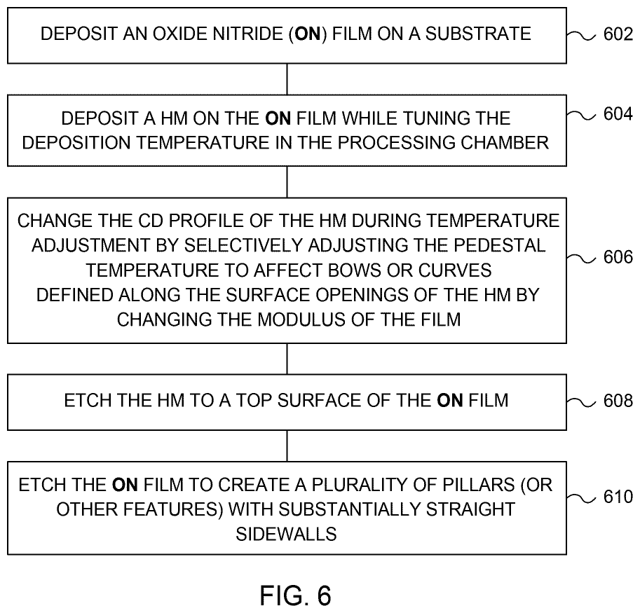

FIG. 6 is a flowchart of a method for adjusting the CD etch profile of the HM using a temperature adjustment approach, according to one implementation.

At block 602, an oxide nitride (ON) film is deposited on a substrate.

At block 604, a HM is deposited on the ON film while adjusting the deposition temperature in the chamber using the pedestal heater temperature or temp knobs. In this instance, the HM does not include initiation layer.

At block 606, the CD profile of the HM is changed during temperature adjustment by selectively adjusting the pedestal temperature to affect bows or curves defined along the surface openings of the HM by changing the modulus of the film.

At block 608, the HM is etched to a top surface of the ON film.

At block 610, the ON film is etched to create a plurality of pillars or other features with substantially straight sidewalls.

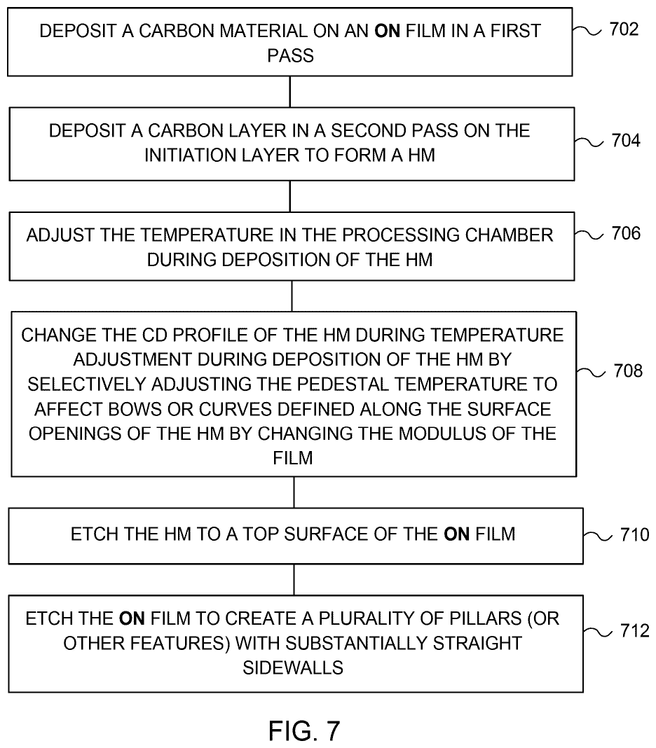

FIG. 7 is a flowchart of a method for adjusting the CD etch profile of the HM using a combination of the initiation layer approach and the temperature adjustment approach, according to one implementation.

At bock 702, a carbon material is deposited on an ON film in a first pass, the carbon material being an initiation layer configured to further open a bottom CD of a HM.

At block 704, a carbon layer is deposited in a second pass on the initiation layer to form the HM. The HM includes both the carbon layer and the initiation layer as its base layer.

At block 706, the temperature of the pedestal is adjusted during deposition of the HM using the pedestal heater temperature or temp knobs.

At block 708, the CD profile of the HM is changed during temperature adjustment during deposition of the HM by selectively adjusting the pedestal temperature to affect bows or curves defined along the surface openings of the HM by changing the modulus of the film.

At block 710, the HM is etched to a top surface of the ON film.

At block 712, the ON film is etched to create a plurality of pillars or other features with substantially straight sidewalls.

Benefits of the present disclosure include precisely etching the HM by changing the CD etch profile of the HM to create straighter openings within the HM. The straighter openings within the HM provide for the creation of pillars with straighter sidewalls in the underlying layers. By adjusting the CD etch profile of the HM, desired device characteristics, better performance, and better device construction reliability may be achieved. By creating a better CD etch profile of the HM (i.e., straighter openings), the systems and methods described herein enable the transfer of patterns with high fidelity, dimensional control, and compatibility with subsequent processing steps, leading to the production of advanced semiconductor devices. Precise etching of the hardmask by adjusting the CD etch profile of the HM results in uniform and consistent device characteristics from one substrate to another, which is beneficial in achieving high manufacturing yield and reliable device performance, and which is beneficial in the production of smaller and more efficient semiconductor devices with enhanced functionality.

In conclusion, the example embodiments optimize the CD etch profile of a hardmask (HM) to create etch uniformity for underlying material layers. The CD etch profile of the HM is adjusted by employing either an initiation layer approach, a temperature tuning approach, or a combination of the initiation layer approach and the temperature tuning approach. Such approaches open the bottom portion of the CD etch profile of the HM to create straight or linear surface openings within the HM that result in the creation of straight pillars in underlying material layers. Thus, the shape of the openings of the HM affect the shape of the pillars formed in the underlying material layers. The shape of the pillars formed in the underlying material layers may affect the semiconductor device operation.

While this specification contains many specific implementation details, these should not be construed as limitations on the scope of what may be claimed, but rather as descriptions of features that may be specific to particular implementations. Certain features that are described in this specification in the context of separate implementations may also be implemented, in combination, in a single implementation. Conversely, various features that are described in the context of a single implementation may also be implemented in multiple implementations, separately, or in any suitable sub-combination. Moreover, although previously described features may be described as acting in certain combinations and even initially claimed as such, one or more features from a claimed combination may, in some cases, be excised from the combination, and the claimed combination may be directed to a sub-combination or variation of a sub-combination.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional) to achieve desirable results. In certain circumstances, multitasking or parallel processing (or a combination of multitasking and parallel processing) may be advantageous and performed as deemed appropriate. While the various steps in an embodiment method or process are presented and described sequentially, one of ordinary skill in the art will appreciate that some or all of the steps may be executed in different order, may be combined, or omitted, and some or all of the steps may be executed in parallel. The steps may be performed actively or passively. The method or process may be repeated or expanded to support multiple components or multiple users within a field environment. Accordingly, the scope should not be considered limited to the specific arrangement of steps shown in a flowchart or diagram.

Furthermore, any claimed implementation is considered to be applicable to at least a computer-implemented method; a non-transitory, computer-readable medium storing computer-readable instructions to perform the computer-implemented method; and a computer system including a computer memory interoperability coupled with a hardware processor configured to perform the computer-implemented method or the instructions stored on the non-transitory, computer-readable medium.

As used herein, “a CPU”, “controller”, “a processor”, “at least one processor”, or “one or more processors”, generally refers to a single processor configured to perform one or multiple operations or multiple processors configured to collectively perform one or more operations. In the case of multiple processors, the one or more operations could be divided amongst different processors, though one processor may perform multiple operations, and multiple processors could collectively perform a single operation. Similarly, “a memory”, “at least one memory”, or “one or more memories”, generally refers to a single memory configured to store data and/or instructions, multiple memories configured to collectively store data and/or instructions.

As used herein, “gas” and “fluid” may be used interchangeable with either term generally referring to elements, compounds, materials, etc., having the properties of a gas, a fluid, or both a gas and a fluid.

Unless defined otherwise, all technical and scientific terms used have the same meaning as commonly understood by one of ordinary skill in the art to which these systems, apparatuses, methods, processes and compositions belong.

In this disclosure, the terms “top”, “bottom”, “side”, “above”, “below”, “up”, “down”, “upward”, “downward,” “horizontal,” “vertical,” and the like do not refer to absolute directions. Instead, these terms refer to directions relative to a nonspecific plane of reference. This non-specific plane of reference may be vertical, horizontal, or other angular orientation.

The singular forms “a”, “an”, and “the”, include plural referents, unless the context clearly dictates otherwise. Within a claim, reference to an element in the singular is not intended to mean “one and only one” unless specifically so stated, but rather “one or more”. Unless specifically stated otherwise, the term “some” refers to one or more.

Embodiments of the present disclosure may suitably “comprise”, “consist”, or “consist essentially of”, the limiting features disclosed, and may be practiced in the absence of a limiting feature not disclosed. As used here and in the appended claims, the words “comprise”, “has”, and “include”, and all grammatical variations thereof are each intended to have an open, non-limiting meaning that does not exclude additional elements or steps.

“Optional” and “optionally” means that the subsequently described material, event, or circumstance may or may not be present or occur. The description includes instances where the material, event, or circumstance occurs and instances where it does not occur.

“Coupled” and “coupling” means that the subsequently described material is connected to previously described material. The connection may be a direct, or indirect connection, and may, or may not, include intermediary components such as plumbing, wiring, fasteners, mechanical power transmission, electrical communication, wired and/or wireless transmission, etc., which may be suitable to affect operation of the components.

As used, the term “determining” encompasses a wide variety of actions. For example, “determining” may include calculating, computing, processing, deriving, investigating, looking up, for example, looking up in a table, a database, or another data structure, and ascertaining. In addition, “determining” may include receiving, for example, receiving information, and accessing, for example, accessing data in a memory. In addition, “determining” may include resolving, selecting, choosing, and establishing.

When the word “approximately” or “about” are used, this term may mean that there may be a variance in value of up to ±10%, of up to 5%, of up to 2%, of up to 1%, of up to 0.5%, of up to 0.1%, or up to 0.01%.

Ranges may be expressed as from about one particular value to about another particular value, inclusive. When such a range is expressed, it is to be understood that another embodiment is from the one particular value to the other particular value, along with all particular values and combinations thereof within the range.

As used, terms such as “first” and “second” are arbitrarily assigned and are merely intended to differentiate between two or more components of a system, an apparatus, or a composition. It is to be understood that the words “first” and “second” serve no other purpose and are not part of the name or description of the component, nor do they necessarily define a relative location or position of the component. Furthermore, it is to be understood that that the mere use of the term “first” and “second” does not require that there be any “third” component, although that possibility is envisioned under the scope of the various embodiments described.

Although only a few example embodiments have been described in detail, those skilled in the art will readily appreciate that many modifications are possible in the example embodiments without materially departing from the disclosed scope as described. Accordingly, all such modifications are intended to be included within the scope of this disclosure as defined in the following claims. In the claims, means-plus-function clauses are intended to cover the structures described as performing the recited function and not only structural equivalents, but also equivalent structures. It is the express intention of the applicant not to invoke 35 U.S.C. § 112(f), for any limitations of any of the claims, except for those in which the claim expressly uses the words ‘means for’ together with an associated function.

While the foregoing is directed to embodiments of the present disclosure, other and further embodiments of the disclosure may be devised without departing from the basic scope thereof, and the scope thereof is determined by the claims that follow.

What is claimed is:

1. A method, comprising:
forming an initiation layer on a dielectric film in a first pass;
forming a carbon layer on the initiation layer in a second pass, the initiation layer and the carbon layer collectively defining a hardmask (HM), and the initiation layer configured to adjust a critical dimension (CD) etch profile of the HM;
etching the HM to a top surface of the dielectric film; and
etching the dielectric film to create a plurality of pillars with straight sidewalls.

2. The method of claim 1, wherein adjusting the CD etch profile of the HM results in substantially straight HM sidewall openings.

3. The method of claim 2, wherein formation of the substantially straight HM sidewall openings cause the plurality of pillars to have straight sidewalls.

4. The method of claim 1, wherein the initiation layer changes a modulus of the HM to adjust the CD etch profile of the HM.

5. The method of claim 1, wherein adjusting the CD etch profile of the HM involves re-shaping bows formed along surface openings of the HM.

6. The method of claim 1, wherein the CD etch profile of the HM can be further adjusted by tuning a HM deposition temperature.

7. The method of claim 1, wherein the initiation layer has a thickness of a 11 kÅ and the carbon layer has a thickness of 22 kÅ.

8. The method of claim 1, wherein the initiation layer is carbon-based with 5-40% hydrogen composition.

9. A method, comprising:
forming a hardmask (HM) on a dielectric film;
adjusting a temperature during deposition of the HM to adjust a critical dimension (CD) etch profile of the HM;
etching the HM to a top surface of the dielectric film; and
etching the dielectric film to create a plurality of pillars with straight sidewalls.

10. The method of claim 9, wherein the temperature is tuned using a heater embedded in a pedestal of a chamber.

11. The method of claim 9, wherein the temperature changes a modulus of the HM to adjust the CD etch profile of the HM.

12. The method of claim 9, wherein adjusting the CD etch profile of the HM results in substantially straight HM sidewall openings.

13. The method of claim 12, wherein formation of the substantially straight HM sidewall openings cause the plurality of pillars to have straight sidewalls.

14. The method of claim 9, wherein adjusting the CD etch profile of the HM involves re-shaping bows formed along surface openings of the HM.

15. The method of claim 9, wherein the dielectric film is an oxide nitride (ON) film.

16. A method, comprising:
forming an initiation layer on a dielectric film in a first pass, wherein the initiation layer is carbon-based with 5-40% hydrogen composition;
forming a carbon layer on the initiation layer in a second pass, the initiation layer and the carbon layer collectively defining a hardmask (HM);
adjusting a temperature during deposition of the HM, wherein forming the initiation layer and adjusting a temperature during deposition of the HM collectively adjust a critical dimension (CD) etch profile of the HM;
etching the HM to a top surface of the dielectric film; and
etching the dielectric film to create a plurality of pillars with straight sidewalls.

17. The method of claim 16, wherein the temperature is tuned using a heater embedded in a pedestal of a chamber.

18. The method of claim 16, wherein the temperature and the initiation layer change a modulus of the HM to adjust the CD etch profile of the HM.

19. The method of claim 16, wherein adjusting the CD etch profile of the HM results in substantially straight HM sidewall openings, wherein formation of the substantially straight HM sidewall openings cause the plurality of pillars to have straight sidewalls.

20. The method of claim 16, wherein adjusting the CD etch profile of the HM involves re-shaping bows formed along surface openings of the HM.
